(19) United States
(12) Patent Application Publication
(10) Pub. No.: US 2017/0062516 A1
(43) Pub. Date: Mar. 2, 2017

(54) LIGHT EMITTING DIODE (LED) ELEMENT

(71) Applicant: ADVANCED OPTOELECTRONIC TECHNOLOGY, INC., Hsinchu Hsien (TW)

(72) Inventors: CHIEN-CHUNG PENG, Hsinchu (TW); TZU-CHIEN HUNG, Hsinchu (TW); CHIH-JUNG LIU, Hsinchu (TW)

(21) Appl. No.: 14/861,777

(22) Filed: Sep. 22, 2015

(30) Foreign Application Priority Data
Aug. 28, 2015 (CN) 201510537906.1

(51) Int. Cl. H01L 27/15; H01L 33/46; H01L 33/50; H01L 33/38; H01L 33/42

(52) U.S. Cl. CPC H01L 27/156; H01L 33/38; H01L 33/42; H01L 33/505; H01L 33/46

(57) ABSTRACT

A light emitting diode (LED) element includes a first conducting layer, a light emitting layer and a second conducting layer. The light emitting layer and the second conducting layer successively are stacked on the first conducting layer. The first conducting layer includes a plurality of first electrodes spaced apart from each other. The second conducting layer includes a plurality of transparent electrodes spaced apart from each other. The light emitting layer includes a plurality of light emitting structures spaced apart from each other and isolated from each other. The light emitting structures are respectively electrically connected with different first electrodes or different second electrodes.

### CROSS-REFERENCE TO RELATED APPLICATIONS

This application claims priority to Chinese Patent Application No. 201510537906.1 filed on Aug. 28, 2015, the contents of which are incorporated by reference herein.

### FIELD

The subject matter relates to a light emitting diode (LED) element, particularly to the LED element for a display field.

### BACKGROUND

Liquid crystal displays (LCDs) are used in the display field. LCDs require the use of a backlight. The backlight is typically a fluorescent bulb.

### BRIEF DESCRIPTION OF THE DRAWINGS

Implementations of the present technology will now be described, by way of example only, with reference to the attached figures.

FIG. 1 is a top, plan view of an LED element in accordance with an exemplary embodiment of the present disclosure.

FIG. 2 is a cross sectional view showing the LED element of FIG. 1, taken along line II-II thereof.

FIG. 3 is a cross sectional view showing the LED element of FIG. 1, taken along line thereof.

### DETAILED DESCRIPTION OF EMBODIMENTS

It will be appreciated that for simplicity and clarity of illustration, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure. The description is not to be considered as limiting the scope of the embodiments described herein.

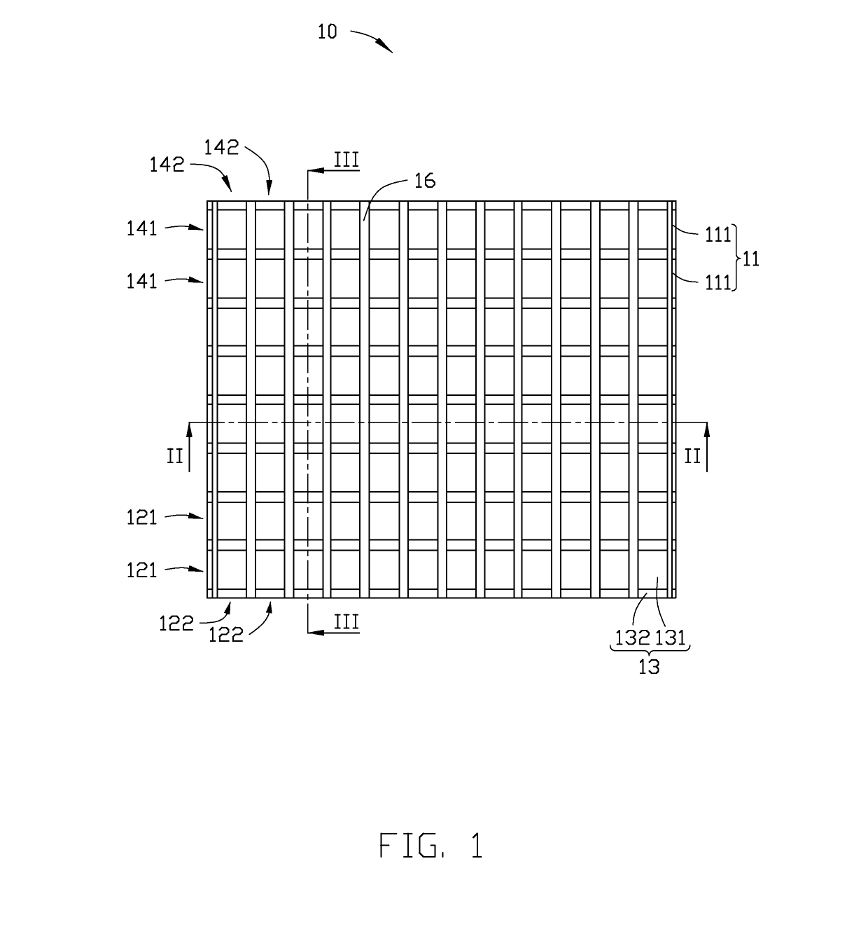

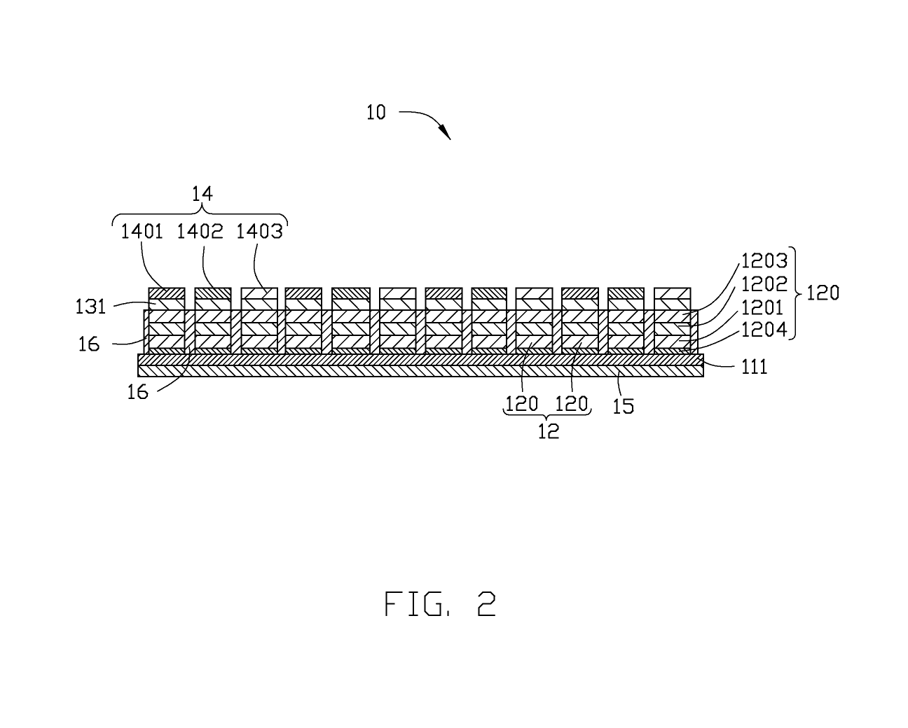

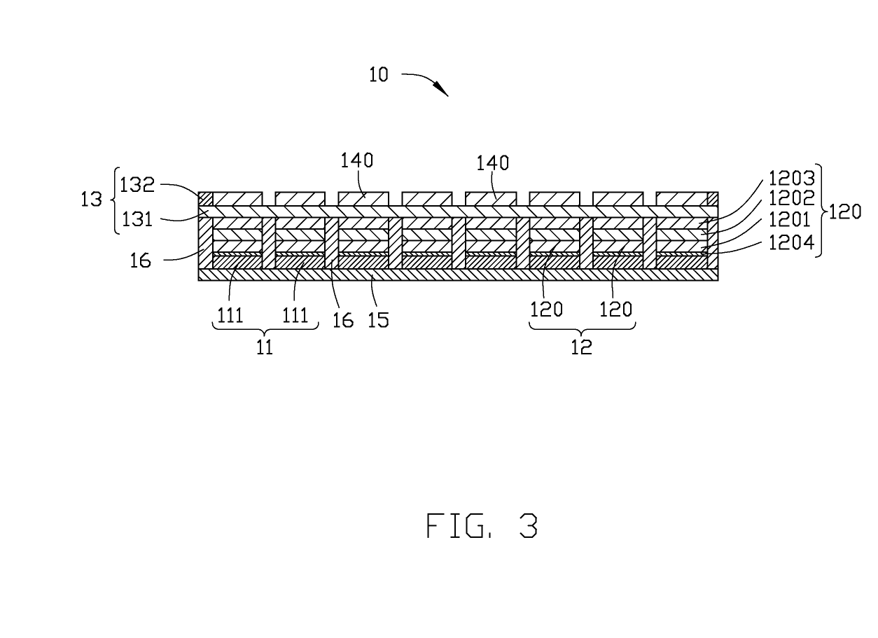

FIGS. 1-3 illustrate an LED element 10 as described by the present disclosure. The LED element 10 includes a first conducting layer 11, a light emitting layer 12 and a second conducting layer 13. The light emitting layer 12 is electrically connected between the first conducting layer 11 and the light emitting layer 12.

The first conducting layer 11 includes a plurality of first electrodes 111 spaced apart from each other. The first electrodes 111 can be parallel to each other. Each first electrode 111 can be a strip.

The light emitting layer 12 is stacked on the first conducting layer 11. The light emitting layer 12 includes a plurality of light emitting structures 120 spaced apart from each other and isolated from one another. A plurality of light emitting rows 121 and a plurality of light emitting columns 122 are arranged by the light emitting structures 120 of light emitting layer 12. The light emitting rows 121 are parallel to each other and spaced apart from each other. The light emitting columns 122 are parallel to each other and spaced apart from each other. Each light emitting row 121 is perpendicular to each light emitting column 122.

Each light emitting structure 120 includes a first semiconductor layer 1201, an active layer 1202 and a second semiconductor layer 1203. The first semiconductor layer 1201, the active layer 1202 and the second semiconductor layer 1203 are successively stacked on the first electrode 111. In the illustrated embodiment, the first semiconductor layer 1201 is an N-doped semiconductor, and the second semiconductor layer 1203 is a P-doped semiconductor. In at least one embodiment, the first semiconductor layer 1201 can be the P-doped semiconductor, and the second semiconductor layer 1203 can be the N-doped semiconductor. In at least one example, the active layer 1202 can be a single quantum well structure. In at least one embodiment, the active layer 1202 can be a multiple quantum well structure. In at least one embodiment, each light emitting structure 120 can emitted ultraviolet light. A length of each light emitting structure 120 can range from 5 μm to 50 μm. A width of each light emitting structure 120 can range from 5 μm to 50 μm.

Each light emitting structure 120 can further include a reflective layer 1204. The reflective layer 1204 can be formed between the first semiconductor layer 1201 and the first electrode 111. The reflective layer 1204 can be made of conducting materials.

The second conducting layer 13 is stacked on the light emitting layer 12. The second conducting layer 13 includes a plurality of transparent electrodes 131 spaced apart from each other. The transparent electrodes 131 are parallel to each other. Each transparent electrode 131 can be a strip.

The light emitting structures 120 are respectively electrically connected between different first electrodes 111 or different transparent electrodes 131. In the illustrated embodiment, the light emitting structures 120 arranged in each light emitting row 121 are formed on and electrically connected to a same first electrode 111, and the light emitting structures 120 arranged in each light emitting column 122 are formed on and electrically connected to different first electrodes 111. The light emitting structures 120 arranged in each light emitting row 121 are formed under and are electrically connected to different transparent electrodes 131, and the light emitting structures 120 arranged in each light emitting column 122, are formed under and are electrically connected to a same transparent electrode 131. Each first electrode 111 can be perpendicular to each transparent electrode 131.

The LED element 10 can further include a fluorescent layer 14. The fluorescent layer 14 is stacked on the transparent electrodes 131. The fluorescent layer 14 can include a plurality of fluorescent units 140 spaced apart from each other. Each fluorescent unit 140 corresponds to one light emitting structure 120 and position upon the light emitting structure 120. A plurality of fluorescent rows 141 and a plurality of fluorescent columns 142 are arranged by the fluorescent units 140. The fluorescent rows 141 are parallel to each other and spaced apart from each other. The fluorescent columns 142 are parallel to each other and spaced apart from each other. Each fluorescent row 141 is perpendicular to each fluorescent column 142. Each fluorescent row 141 corresponds to one light emitting row 121 and position upon the light emitting row 121. Each fluorescent column 142 corresponds to one light emitting column 122 and position upon the light emitting column 122.

The fluorescent unit 140 can includes a plurality of red fluorescent units 1401, a plurality of green fluorescent units 1402 and a plurality of blue fluorescent units 1403. In the illustrated embodiment, each fluorescent row 141 has the red fluorescent unit 1401, the green fluorescent unit 1402 and the blue fluorescent unit 1403 followed in order by another red fluorescent unit 1401, green fluorescent unit 1402 and blue fluorescent unit 1403 each fluorescent column 142 has one of: the red fluorescent unit 1401, the green fluorescent unit 1402 and the blue fluorescent unit 1403. In at least one embodiment, each fluorescent column 142 has the red fluorescent unit 1401, the green fluorescent unit 1402 and the blue fluorescent unit 1403 repeated by an order of the red fluorescent unit 1401, the green fluorescent unit 1402 and the blue fluorescent unit 1403, and in each fluorescent row 141 has one of three in the red fluorescent unit 1401, the green fluorescent unit 1402 and the blue fluorescent unit 1403.

The second conducting layer 13 can further include a plurality of second electrodes 132 electrically connected to the transparent electrodes 131. Two second electrodes 132 are respectively positioned at two ends of each transparent electrode 131. In the illustrated embodiment, the second electrodes 132 are formed on the transparent electrodes 131. A thickness of the fluorescent layer 14 is substantially equal to a thickness of the second electrodes 132.

The LED element 10 can further include a substrate 15. The first conducting layer 11 is stacked on the substrate 15. The substrate 15 can be made of sapphire (Al₂O₃), silicon carbide (SiC), silicon (Si) or gallium nitride (GaN).

The LED element 10 can further include an isolating layer 16. The isolating layer 16 can be formed between the first electrodes 111. The isolating layer 16 can be formed between the light emitting structures 120 and around the light emitting structures 120. The isolating layer 16 can be made of opaque materials.

The embodiments shown and described above are only examples. Many details are often found in the art such as the other features of an LED element. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

1. A light emitting diode (LED) element comprising:
a first conducting layer comprising a plurality of first electrodes spaced apart from each other;
a light emitting layer stacked on the first conducting layer and comprising a plurality of light emitting structures spaced apart from each other and isolated from one another; and
a second conducting layer stacked on the light emitting layer and comprising a plurality of transparent electrodes spaced apart from each other;
wherein the plurality of light emitting structures comprises a first group of light emitting structures, and a second group of light emitting structures;
wherein a portion of the plurality of light emitting structures of the first group are electrically connected to the same first electrodes of the plurality of first electrodes, and
another portion of the plurality of light emitting structures of the first group are each electrically connected to different transparent electrodes of the plurality of transparent electrodes; and
wherein a portion of the plurality of light emitting structures of the second group are electrically connected to the same transparent electrodes of the plurality of transparent electrodes, and
another portion of the plurality of light emitting structures of the second group are each electrically connected to different first electrodes of the plurality of first electrodes;
wherein each of the plurality of light emitting structures comprises a reflective layer, and each reflective layer is formed on each of the plurality of first electrodes, wherein the reflective layer is made of electrical conducting materials.

2. The LED element of claim 1, wherein the plurality of light emitting structures is arranged in rows and columns.

3. (canceled)

4. The LED element of claim 2, wherein the plurality of light emitting structures arranged in each of the rows are formed on and electrically connected to the same first electrode, and the plurality of light emitting structures arranged in each of the columns are each formed on and each electrically connected to different first electrodes.

5. The LED element of claim 2, wherein the plurality of light emitting structures arranged in each of the rows are each formed under and each electrically connected to different transparent electrodes, and the plurality of light emitting structures arranged in each of the columns are formed under and electrically connected to the same transparent electrode.

6. The LED element of claim 2, further comprises a fluorescent layer stacked on the plurality of transparent electrodes.

7. The LED element of claim 6, wherein the fluorescent layer comprises a plurality of fluorescent units spaced apart from each other, and each of the plurality of fluorescent units correspond to and positioned upon one of the plurality of light emitting structures.

8. The LED element of claim 7, wherein the plurality of fluorescent units are arranged in rows and columns.

9. The LED element of claim 8, wherein the rows of the plurality of fluorescent units are parallel to each other and spaced apart from each other.

10. The LED element of claim 6, wherein the second conducting layer further comprises a plurality of second electrodes, each two of the plurality of second electrodes are respectively positioned at two ends of one of the plurality of transparent electrodes.

11. The LED element of claim 10, wherein each two of the plurality of second electrodes are respectively formed on two ends of one of the plurality of transparent electrodes.

12. The LED element of claim 8, wherein the columns of the plurality of fluorescent units are parallel to each other and spaced apart from each other.

13. (canceled)

14. The LED element of claim 8, wherein each of the rows of the plurality of fluorescent units correspond to and positioned upon one of the rows of the plurality of light emitting structures.

15. The LED element of claim 8, wherein each of the columns of the plurality of fluorescent units correspond to and positioned upon one of the columns of the plurality of light emitting structures.

16. The LED element of claim 8, wherein each of the plurality of fluorescent units is made from a red fluorescent unit, a green fluorescent unit, or a blue fluorescent unit.

17. The LED element of claim 1, further comprising a substrate, the first conducting layer being stacked on the substrate.

18. (canceled)

19. The LED element of claim 1, wherein each of the plurality of first electrodes is perpendicular to one of the plurality of transparent electrodes.

20. The LED element of claim 1, further comprising an isolating layer formed between the plurality of light emitting structures and around the plurality of light emitting structures.
